(19) United States
(12) Patent Application Publication
(10) Pub. No.: US 2008/0192431 A1
(43) Pub. Date: Aug. 14, 2008

(54) COMPACT RACKMOUNT SERVER

(75) Inventor: Andreas V. Bechtolsheim, Palo Alto, CA (US)

Correspondence Address: OSHA LIANG L.L.P./SUN, 1221 MCKINNEY, SUITE 2800, HOUSTON, TX, 77010, US

(73) Assignee: SUN MICROSYSTEMS, INC., Santa Clara, CA (US)

(21) Appl. No.: 12/101,773

(22) Filed: Apr. 11, 2008

Related U.S. Application Data
(63) Continuation of application No. PCT/US2007/000958, filed on Jan. 12, 2007.
(60) Provisional application No. 60/758,948, filed on Jan. 13, 2006.

(51) Int. Cl. H05K 7/20

(52) U.S. Cl. 361/695

(57) ABSTRACT

A rackmount server has dual-redundant hot-swappable fans for uniformly providing air flow to a plurality of CPU modules housed in the rackmount server. Air flow generated by the fans may also be provided to I/O circuitry disposed in the rackmount server. An airflow zone in which air flow is provided by the fans is separate, however, from an airflow zone in which air flow is provided to at least one power supply and/or disk drive housed in the rackmount server.

### BACKGROUND

As generally referred to in the art, a “server” is a computing device that is configured to perform operations for one or more other computing devices connected over a network. For an entity that requires computing infrastructure for handling relatively large amounts of network data, it is desirable to use servers that are designed to promote organizational/space efficiency and operational performance. In this regard, some servers are designed to be arranged in a “rack,” whereby the rack (or “cabinet”) houses numerous servers that are arranged, or “mounted,” vertically one on top of another (however, not necessarily in contact with one another). Such a server is generally referred to in the art as a “rackmount” server.

Rackmount servers are generally designed having a height corresponding to whole multiples of an industry standard rack mounting height dimension. For example, rackmount servers are generally referred to as “2U,” “3U,” “4U,” etc. systems, where the “U” designation refers to one dimensional increment of 1.75 inches in height along the vertical members of an Electronics Industry Alliance (EIA) industry-standard computer racking/mounting structure. Thus, for example, a 2U rackmount server is generally designed to be approximately 3.5 inches in height, less a small amount of clearance between vertically-adjacent rackmount servers in the rack (those skilled in the art will note that a standard rack is 19 inches wide; however, racks of other widths are available).

In view of size constraints and limitations of a rackmount server, it is important to combine and arrange components in the rackmount server in a manner that promotes operational performance and space efficiency.

### SUMMARY

According to one aspect of one or more embodiments of the present invention, a server comprises: a plurality of fans arranged along a inside surface of a front side of the server; a printed circuit board (PCB) disposed behind the plurality of fans; a plurality of CPU modules operatively connected to the PCB; and a plurality of I/O components disposed behind the plurality of CPU modules.

According to another aspect of one or more embodiments of the present invention, an apparatus comprises: a first section having (i) dual-redundant cooling devices, (ii) a PCB disposed behind the dual-redundant cooling devices, and (iii) at least one CPU module vertically connected to the PCB; and a second section having (i) at least one disk drive accessible from a first side of the apparatus, (ii) at least one power supply accessible from a second side of the apparatus, and (iii) at least one cooling device disposed between the at least one disk drive and the at least one power supply, where airflow in the first section is separate from airflow in the second section.

According to another aspect of one or more embodiments of the present invention, a rackmount server comprises: dual-redundant hot-swappable fans disposed along a front vented inner surface of the rackmount server; a plurality of CPU modules operatively connected to a backplane horizontally disposed behind the dual-redundant hot-swappable fans; and I/O circuitry disposed behind the plurality of CPU modules, where a first airflow zone in which air flow is provided by the dual-redundant hot-swappable fans to the plurality of CPU modules is separate from a second airflow zone in which air flow is provided to an internal power supply unit of the rackmount server.

Other aspects of the present invention will be apparent from the following description and the appended claims.

### BRIEF DESCRIPTION OF DRAWINGS

FIG. 1 shows a rackmount server in accordance with an embodiment of the present invention.

FIG. 2A shows a front side perspective view of a portion of a rackmount server in accordance with an embodiment of the present invention.

FIG. 2B shows a rear side perspective view of a portion of a rackmount server in accordance with an embodiment of the present invention.

FIG. 3 shows a portion of a rackmount server in accordance with an embodiment of the present invention.

FIG. 4 shows a portion of a rackmount server in accordance with an embodiment of the present invention.

FIG. 5 shows a portion of a rackmount server in accordance with an embodiment of the present invention.

FIG. 6 shows a portion of a rackmount server in accordance with an embodiment of the present invention.

FIG. 7 shows an exploded view of a portion of a rackmount server in accordance with an embodiment of the present invention.

FIG. 8 shows system components of an exemplary embodiment of a rackmount server.

FIG. 9 shows a block diagram of an exemplary embodiment of a rackmount server.

FIG. 10 shows a block diagram of an exemplary embodiment of a rackmount server.

FIG. 11 shows the front face plate of the chassis of an exemplary embodiment of a rackmount server.

FIG. 12 shows the rear face of the chassis of an exemplary embodiment of a rackmount server.

FIG. 13 shows a USB connector.

FIG. 14 shows a Serial connector.

FIG. 15 shows a VGA connector.

FIG. 16 shows a 10/100/1000BaseT connector.

FIG. 17 shows a Serial Attached SCSI (SAS) connector.

### DETAILED DESCRIPTION

Specific embodiments of the present invention will now be described in detail with reference to the accompanying figures. Like elements in the various figures are denoted by like reference numerals for consistency. Further, in the following detailed description of embodiments of the present invention, numerous specific details are set forth in order to provide a more thorough understanding of the present invention. In other instances, well-known features have not been described in detail to avoid obscuring the description of embodiments of the present invention.

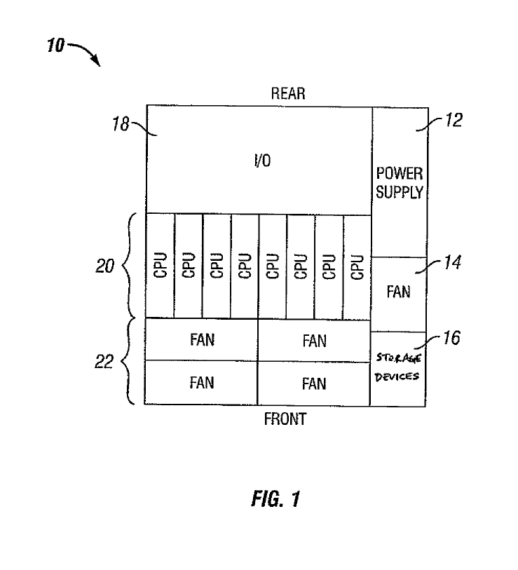

Generally, embodiments of the present invention relate to a rackmount server having a novel combination and/or arrangement of components. FIG. 1 shows an example of a rackmount server 10 in accordance with an embodiment of the present invention. Along a front portion of the rackmount server 10 are positioned a plurality of cooling devices 22. More specifically, in one or more embodiments of the present invention, the cooling devices 22 are implemented as dual-redundant fans. Further, in one or more embodiments of the present invention, these fans may be “hot-swappable,” i.e., changeable during operation (those skilled in the art will note that replacing one or more of the fans may have to occur within some time period so as to prevent overheating).

The cooling devices 22 provide airflow to a plurality of CPU modules 20 (further described below with reference to FIG. 6). The CPU modules 20 may be “plugged into” a printed circuit board (PCB), which may be a backplane (passive or active) or motherboard (not shown) disposed along an inner bottom surface of the rackmount server 10. Further, the PCB (not shown) may be arranged to provide at least one of standard and modular I/O 18.

Further, those skilled in the art will note that although FIG. 1 shows a particular number of CPU modules 20 and cooling devices 22, in one or more other embodiments of the present invention, any number of CPU modules 20 and/or cooling devices 22 may be used.

Still referring to the rackmount server 10 shown in FIG. 1, along a side portion of the rackmount server 10 are disposed one or more storage devices 16. The storage devices 16 may include one or more of a CD drive, a floppy disk drive, and any other type of non-volatile data storage medium.

Further, also along the side portion of the rackmount server 10 are power supplies 12. In one or more embodiments of the present invention, the power supplies 12 may contain four individual power supply units. In one or more other embodiments of the present invention, a different number of power supply units may be used.

Further, a fan 14 provides airflow to the power supplies 12. Thus, fan 14 may also effectively be used to provide airflow to the storage devices 16 due to the position of fan 14 between the storage devices 16 and the power supplies 12.

In the rackmount server 10 shown in FIG. 1, the airflow provided by cooling devices 22 occurs in an airflow zone separate from that in which airflow is provided by the fan 14 to the storage devices 16 and the power supplies 12. This may be achieved by, for example, implementing a wall between the cooling devices 22, the CPU modules 20, and the I/O 18 and the storage devices 16, the fan 14, and the power supplies 12. In other words, the airflow zone for the CPU modules 20 and the I/O 18 is separate from the airflow zone for the storage devices 16 and the power supplies 12.

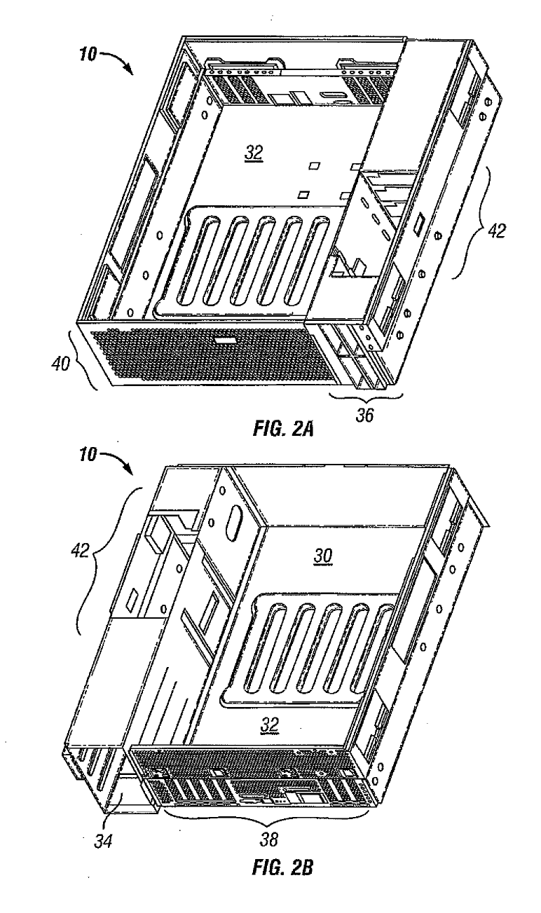

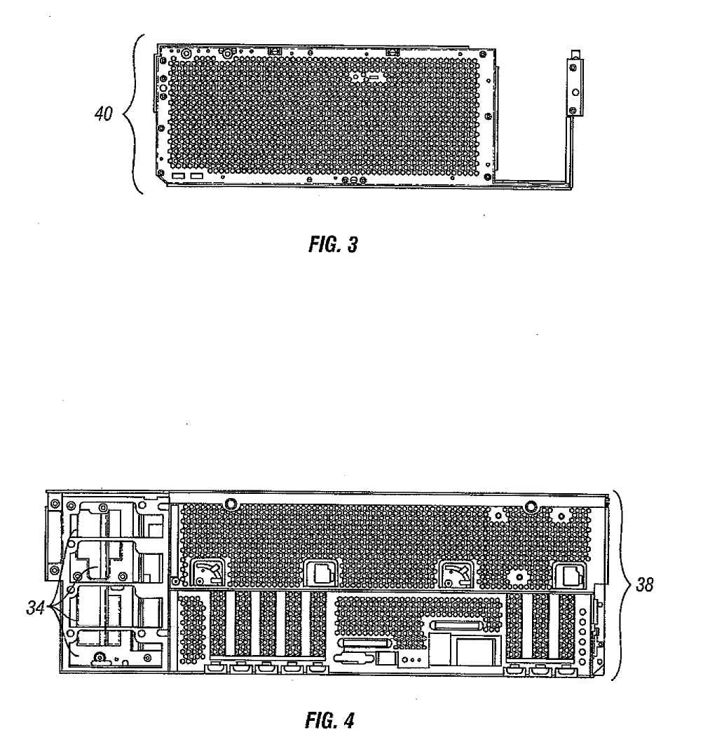

FIG. 2A shows a front side perspective of a rackmount server 10 in accordance with an embodiment of the present invention. In FIG. 2A, a chassis (shown, but not labeled) of the rackmount server 10 has a front side 40 (further described below with reference to FIG. 3) at least partially arranged to allow for airflow between a region interior of the rackmount server 10 and a region exterior of the rackmount server 10. Further, as shown in FIG. 2A, a plurality of slots (or “bays”) 36 for at least partially housing one or more storage devices (not shown) is positioned along a portion of the front side 40. In such a manner, one or more storage devices (not shown) may be removed from and inserted into the rackmount server from the front side 40, thereby easing needed effort to insert or replace one or more storage devices (not shown).

Still referring to FIG. 2A, the chassis (shown, but not labeled) has an area 32 along an inside bottom surface for, for example, I/O components (not shown). Further, an area 42 is provided in the chassis (shown, but not labeled) for at least partially housing one or more fans for providing airflow for any storage devices and power supplies.

FIG. 2B shows a rear side perspective of a rackmount server 10 in accordance with an embodiment of the present invention. In FIG. 2B, the chassis (shown, but not labeled) of the rackmount server 10 has a rear side 38 (further described below with reference to FIG. 4) at least partially arranged to allow for airflow between a region interior of the rackmount server 10 and a region exterior of the rackmount server 10. Further, as shown in FIG. 2B, a plurality of slots (or “bays”) 34 for at least partially housing one or more power supplies (not shown) is positioned along a portion of the rear side 38. In such a manner, one or more power supplies (not shown) may be removed from and inserted into the rackmount server from the rear side 38, thereby easing needed effort to insert or replace one or more power supplies (not shown).

Still referring to FIG. 2B, the chassis (shown, but not labeled) has an area 30 along an inside bottom surface for, for example, cooling devices (not shown). Further, as described above with reference to FIG. 2A, area 42 is provided in the chassis (shown, but not labeled) for at least partially housing one or more fans for providing airflow for any storage devices and power supplies.

As is discernible from FIGS. 2A and 2B, an airflow zone for storage devices and power supplies of the rackmount server 10 is separated from an airflow zone in which airflow is provided to CPU components (not shown).

FIG. 3 shows a front side 40 of a rackmount server 10 in accordance with an embodiment of the present invention. The front side 40 is at least partially formed of a “honeycombed” or vented surface for allowing air to pass through the front side 40. Those skilled in the art will note that providing for such air flow passage results in cooling of one or more components in the rackmount server 10. Further, although not shown in FIG. 3, those skilled in the art will note that, based on FIG. 2A, a plurality of cooling devices (e.g., dual-redundant hot-swappable fans) may be positioned directly behind the front side 40 of the rackmount server 10. In such a manner, there are no components that block air from passing to and/or from cooling devices positioned behind the vented surface of the front side 40 of the rackmount server 10.

FIG. 4 shows a rear side 38 of a rackmount server 10 in accordance with an embodiment of the present invention. The rear side 38 is at least partially formed of a “honeycombed” or vented surface for allowing air to pass through the rear side 38. Those skilled in the art will note that providing for such air flow passage results in cooling of one or more components in the rackmount server 10. Further, those skilled in the art will note that the rear side 38 forms an exit for air flowing in the airflow zone used to cool CPU components in the rackmount server 10. Further, a plurality of slots (or “bays”) 34 are provided to received and at least partially house and provide connectivity for one or more power supplies (not shown) (those skilled in the art will note that although four power supply bays 34 are shown in FIG. 4, a different number of power supply bays may be provided and/or used).

Further, as discernible in FIG. 4, the rear side 38 of the rackmount server 10 may have slots, connectors, and/or other connection means for providing network, power, and/or I/O connectivity for the rackmount server 10.

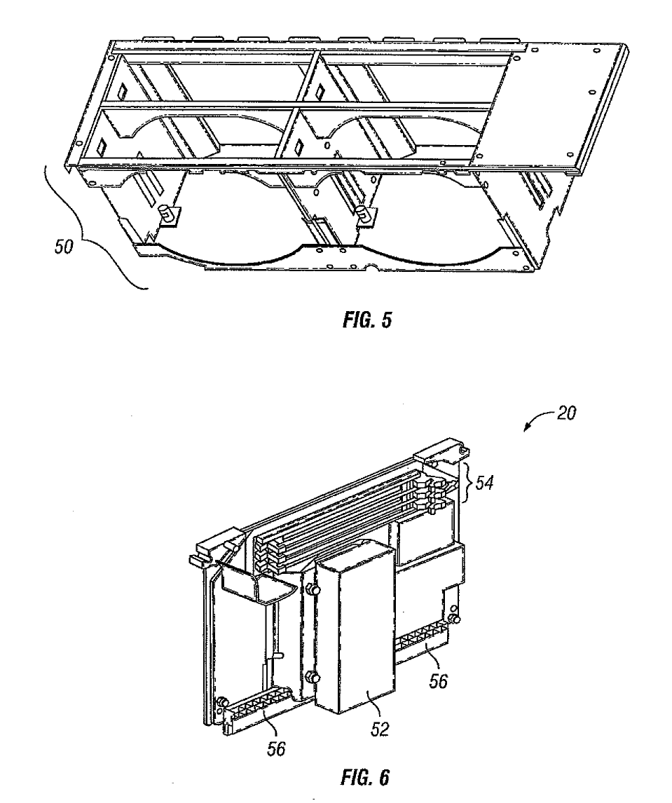

Referring again to FIG. 1, a plurality of cooling devices 22 are used to provide airflow for an airflow zone separate from an airflow zone in which air flow is provided to the storage devices and power supplies. FIG. 5 shows an example of a chassis 50 that may be used to support the plurality of cooling devices 22. More particularly, in one or more embodiments of the present invention, the chassis 50 may be arranged to support dual-redundant hot-swappable fans as described above. The fans are said to be “dual-redundant” because there are two rows of fans. If a fan in one row fails or is otherwise temporarily removed for replacement, the corresponding fan in the adjacent row may be used to compensate for at least some loss in airflow strength resulting from the failure or removal of the first fan. Thus, a failure of a fan does not necessarily result in non-uniform air flow.

Further, in one or more embodiments of the present invention, a fan supported by the chassis 50 may be configured such that it individually provides uniform air flow, or substantially uniform air flow (defined as being air flow sufficient not to require changes in the configuration of components designed and/or expected to operate in uniform air flow conditions). In other words, air flow strength and direction from the fan is uniform across a planar region of the fan.

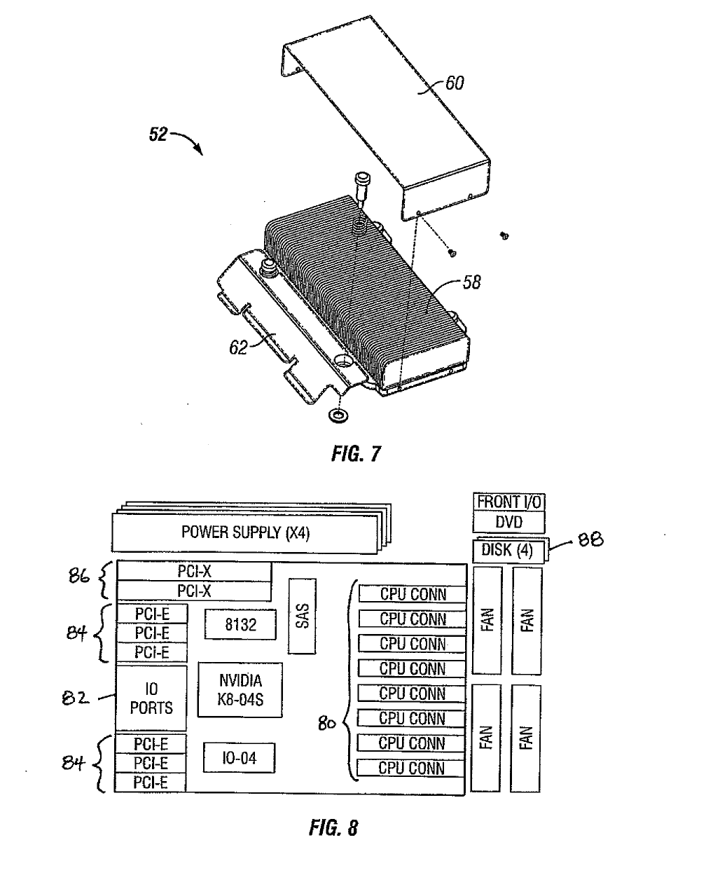

Referring again to FIG. 1, a plurality of CPU modules 20 may be “plugged into” the rackmount server 10. FIG. 6 shows an example of one such CPU module 20. The CPU module 20 includes a microprocessor (or other form of an integrated circuit) (not shown), atop which is disposed a heat sink 52 (further described below with reference to FIG. 7). The CPU module 20 further has a plurality of memory slots 54 for attachment of one or more memory modules (not shown).

The CPU module 20 is “plugged into” a PCB (not shown) residing in the rackmount server 10 by way of a native connector 56 integral with the CPU module 20. Those skilled in the art will note that a configuration of the heat sink 52 is such that it overhangs at least a portion of the native connector 56, thereby providing additional area for heat dissipation.

FIG. 7 shows an exploded view of a heat sink 52 in accordance with an embodiment of the present invention. The actual heat sink body 54 is mounted on a lid 62 that is arranged to be thermally interfaced with a microprocessor (not shown) disposed underneath the lid 62. Further, a cover 60 is attached to the lid 62 and over the heat sink body 54 as shown in FIG. 7.

Advantages of the present invention may include one or more of the following. In one or more embodiments of the present invention, a rackmount server has a combination of cooling devices, CPU modules, and I/O that promotes improved operational performance, reduced or more controlled operating temperatures, and/or increased space efficiency.

In one or more embodiments of the present invention, a rackmount server has an airflow zone for cooling CPU components that is separate from an airflow zone for cooling storage devices and/or power supplies.

In one or more embodiments of the present invention, cooling devices for providing airflow to CPU components and I/O in a rackmount server may be dual-redundant, thereby reducing a likelihood of overheating should one of the cooling devices fail or be removed.

In one or more embodiments of the present invention, cooling devices for providing airflow to the CPU components and I/O in a rackmount server may be hot-swappable, so as to allow for the repair or replacement of a cooling device without having to shut down a system.

In one or more embodiments of the present invention, cooling devices for providing airflow to CPU components and I/O in a rackmount server may be arranged to provide uniform air flow.

In one or more embodiments of the present invention, a cooling device for providing airflow to a power supply in a rackmount server may be used to provide airflow to one or more storage devices in the rackmount server.

In one or more embodiments of the present invention, a heat sink for a CPU module that may be plugged into a rackmount server overhangs at least a portion of the connector used to connect the CPU module to a motherboard residing in the rackmount server, thereby providing for potentially increased heat dissipation.

In one or more embodiments of the present invention, air flow provided to CPU components in a rackmount server is not blocked by one or more storage devices and/or power supplies in the rackmount server.

A detailed example of a rackmount server in accordance with the present invention is presented below in the form of a product specification. This specification describes the functionality, major components and subsystems, external interfaces, and operation of an exemplary server referred to as the Sun Fire X4600 system, available from Sun Microsystems, Inc. The Sun Fire X4600 system components can be seen in FIG. 8.

The Sun Fire X4600 is a modular rack mounted server that has a 4U chassis with 8 CPU modules 80, each supporting one CPU socket, DIMMs, and local power conversion (VRM) on a single board. The modules are inserted from the top of the chassis and connect directly to the rear I/O motherboard. The Sun Fire X4600 provides the following maximum system configurations: 8 CPU chips (single or dual cores); 32 DIMMs (maximum 128 GB with 4 GB DIMM); 4 2.5″ SAS/SATA disks; 8 PCI Expansion slots; 2 PCI-X and 6 PCI-Express. The Sun Fire X4600 is 609 mm (24″) deep and is compatible with datacenter 28″ racks. Airflow is front-to-back and supports AMD Opteron™ processors at 35° C. ambient temperature. Standard I/O ports 82 include four 10/100/1000BaseT Gigabit Ethernet ports, graphics, serial, four USB ports, and an Ethernet management port. For further expansion, the Sun Fire X4600 provides six PCI-Express 84 and two PCI-X slots 86. A SAS/SATA disk controller is provided on board to support 4 SAS-only disk drives 88.

The Sun Fire X4600 includes an extensive set of RAS (Reliability, Availability, and Serviceability) features: hot-swappable and redundant fans and power supplies, remote lights-out server management, remote boot, and remote software upgrades.

The RAS Feature Set has Intelligent Systems Management including: SP (Service Processor); TPM (Trusted Platform Module); ECC Memory and Cache; Hot-swap Cooling Fans; Hot-swap Power Supplies; Temperature and Voltage Monitoring; KVM Redirection over Ethernet. A Sun Fire X4600 feature summary is included below in Table 1.

TABLE 1
The Sun Fire X4600 Feature Summary

| Feature | Specification |
|---|---|
| Processor | AMD64 Opteron ™ single or dual core (1 MByte L2 cache per |
| | CPU core). |
| Processor Configurations | 2, 4, 6, 8, 12, 16 |
| Memory Type | PC3200 (400 MHz) ECC DIMMs |
| Memory Size | 4 DDR-I PC3200 DIMMs per processor socket |
| Memory Capacities | 512 MB, 1 GB, 2 GB, or 4 GB per DIMM |
| Processor BIOS | 8 Mbit Flash with LPC Interface |
| Hard disks | 4 × 2.5″ SAS |
| DVD drive | Slot-loading DVD-ROM Drive |
| Management Processor | Motorola MPC8248 @ 266 MHz |
| Management Interfaces | 10/100BaseT Ethernet port, I2C connection with South Bridge, |
| | Serial port, multiplexed with the system serial port |
| IO Ports | 4 × 10/100/1000BaseT Ethernet (RJ45 Connector) |
| | 1 × 10/100BaseT Ethernet Management port (RJ45 Connector) |
| | 1 × RS-232 Serial Interface (RJ45 Connector) |
| | 4 × USB 2.0 Ports (USB Type A Connector) (2x in front, 2x in |
| | rear) |
| | Graphics Port (VGA Connector) |
| Expansion Slots | 6 Low profile PCI-Express and 2 low profile PCI-X |

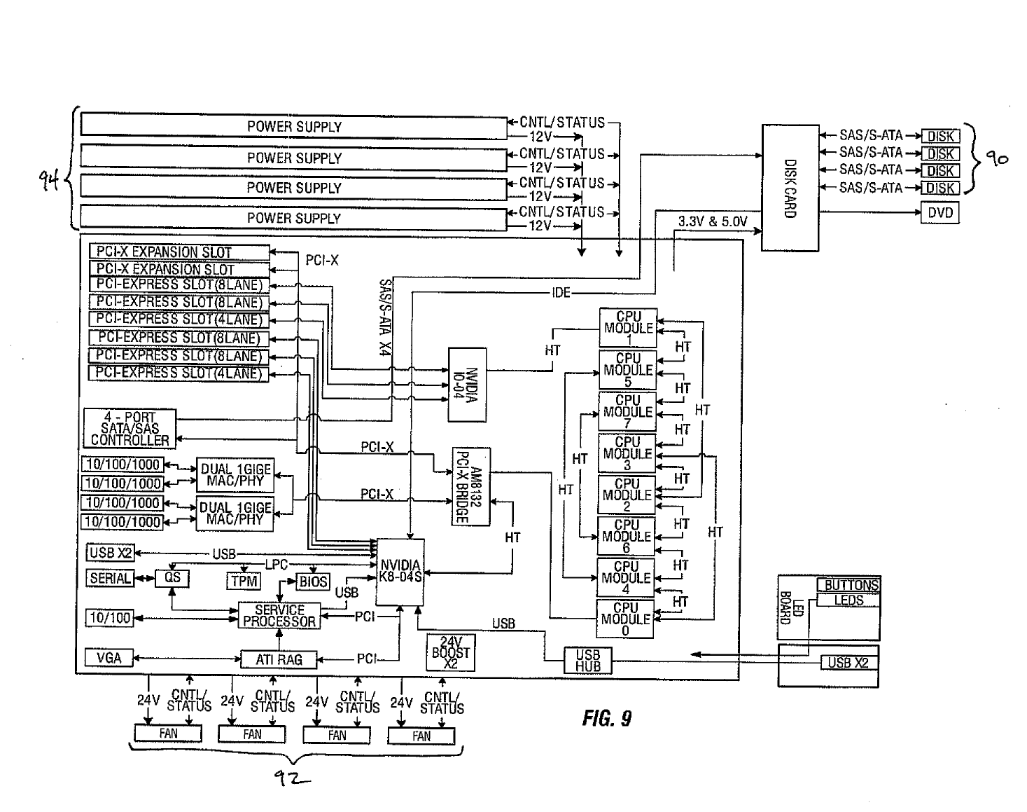

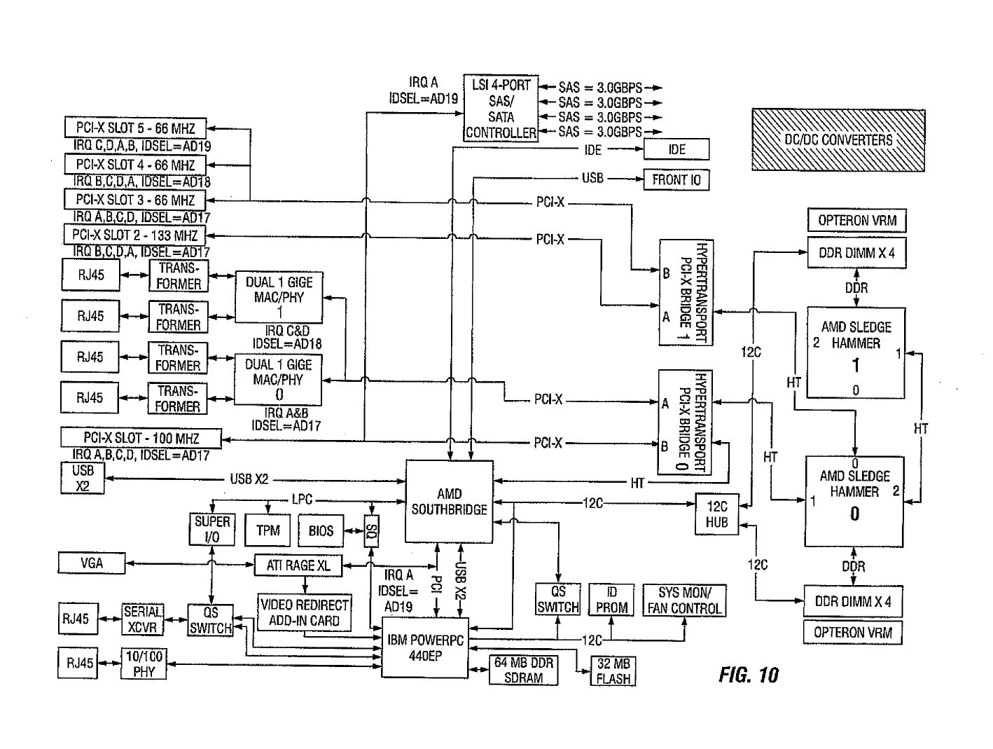

A more detailed block diagram of the Sun Fire X4600 is shown in FIG. 9 and FIG. 10. The Sun Fire X4600 has redundant and hot-swappable disks 90, fans 92, and power supplies 94.

The Sun Fire X4600 provides the external interfaces described in Table 3.

TABLE 3
The Sun Fire X4600 External Interfaces

| Type | Quantity | Connector Type | Description |
|---|---|---|---|
| 100 MHz PCI-X 1.0 | 2 | 64-bit PCI-X | |
| Slots | | | |
| 8-lane PCI-E Slots | 4 | 8-lane PCI-Express | PCI slots 3, 4, 6, and 7 |
| 4-lane PCI-E Slots | 2 | 8-lane PCI-Express | PCI Slots 5 and 8. |
| 10/100/1000BaseT | 4 | RJ45 | |
| Ethernet copper | | | |
| 10/100 Ethernet | 1 | RJ45 | Management port for main |
| copper | | | CPUs and supervisory CPU |
| RS-232 serial port | 1 | RJ45 | Management port |
| USB 2.0 | 4 | USB Type A | 2 rear connectors, 2 front |
| VGA | 1 | High-density DB-15 | Standard VGA connection |
| IDE/ATAPI | 1 | 50-pin IDE connector | Connection on disk |
| | | | backplane for DVD drive |
| SAS/S-ATA | 4 | SAS | Backward compatible to |
| | | | S-ATA. |
| Power button | 1 | N/A | Front-mounted power button |
| Front Visual | 14 | N/A | |
| Indicators | | | |
| Rear Visual Indicators | 3 | N/A | |
| 120/240 V AC input | 4 | Standard IEC-320 | AC input located on power |
| | | connector | supply |

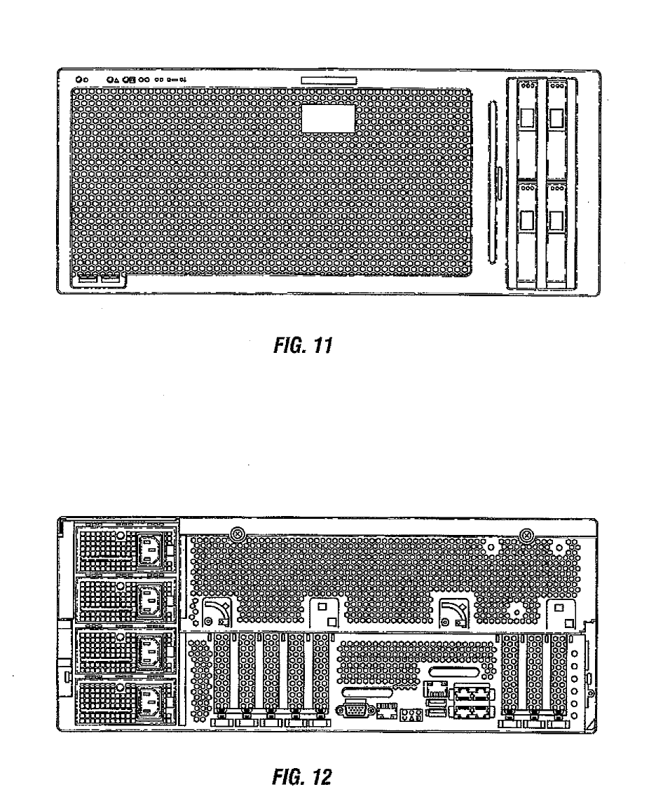

FIG. 11 shows the front face plate of the chassis. FIG. 12 shows the rear face of the chassis. Forced-air cooling for the motherboard is provided by individual fans, e.g., four 172×160×52 mm running at 24V. The fans provide approximately 474 CFM of airflow in the chassis, from the front to the back of the chassis. The fan speed is variable, adjusting for the ambient conditions, the number of processors and DIMMs, and the amount of activity in the system. The fans have a common speed control resulting in Like fan speeds on all four fans.

Fan power is converted on the motherboard from 12 V to 24 V with dual 200 W boost converters. Each converter powers one row. Thus, if one converter fails, the redundant fans can continue to cool the system. The power supplies have an internal fan for cooling. The power supply fans may also provide cooling for the disk drives and DVD drive.

The Sun Fire X4600 system software detects fan failure, provides a front panel failure indication, generates a corresponding failure indication to the management system, and, if need be, places the chassis into a power-down state in a controlled manner. The power-down state minimizes chassis power dissipation, but maintains the SP operation to allow diagnostics and management functions.

The Sun Fire X4600 system software also checks for the presence of the fans. The system requires two fans installed in a row across the chassis to function correctly. If this minimum fan requirement is not met when power is applied to the chassis, the system will not be allow to power on. The system remains in a power-down state until at least one row of fans are installed. If a single fan is missing, an alert is generated indicating the problem. The motherboard contains the PCI-X Bridges, the SouthBridge, the SAS/S-ATA controller, and all I/O connectors. This board also connects to the hot swappable fan modules.

FIG. 13 shows a block diagram of the Sun Fire X4600 PCI-Express I/O Board. All I/O functionality including all external connectors, with the exception of the disk and power connectors, reside on the Sun Fire X4600 motherboard. The motherboard design supports PCI-Express. The motherboard connects the HyperTransport busses between the CPU's and to the I/O blocks.

The mother board also includes the Service Processor (SP) module connector. The SP monitors the system and reports if there is a problem with the system, even if the main processors are hung or dead, or if the main 12V power has failed The SP monitors temperature and voltages, and is powered by the standby 3.3V from the power supplies.

The motherboard has the LSI SAS1064 controller (the “SAS Controller”). The controller shares a bus with the Slot 2 PCI-X slot and is wired to accept a Zero Channel Raid controller in that slot. This board includes one AMD Opteron™ CPU socket, 4 DIMMs, VRMs, IDPROM and sense circuits. The motherboard interconnects all the major system components, and, additionally, interconnects the HyperTransport busses between the CPU modules and the I/O board.

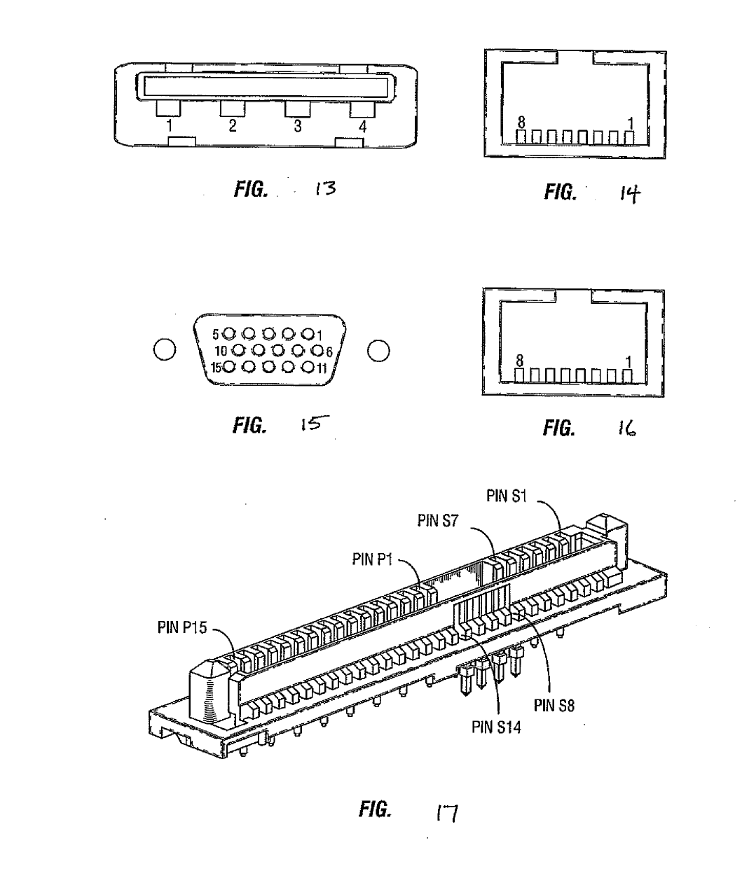

Processors are loaded in pairs in incrementing order, i.e., 0-1, 2-3, 4-5, 6-7. The unused sockets are loaded with a filler module for thermal requirements and electrical performance. The exception is the 2P case in which slots 0 and 4 are loaded and filler cards are not required. The CPU's are connected via the HyperTransport links as shown in the following diagrams. The dangling links connect to the I/O and the filler module jumper links indicating the number of filler boards in the path. FIG. 15 shows the Quad CPU HT Interconnect. FIG. 16 shows the Hex CPU HT Interconnect. FIG. 17 shows the Octal CPU HT Interconnect.

The disk backplane board has the connectors for the four drive bays and connection to the motherboard. A flex circuit is utilized to connect the disk backplane with the DVD drive to the motherboard.

The Sun Fire X4600 uses four load-sharing, n+1 redundant, hot-swappable 850 W power supplies. The power supplies have universal input, 12 VDC primary output and 3.3V standby. Main 12V power is connected to the Motherboard via a bus bar. Standby power and other control signals are routed via a flex circuit to the motherboard.

The power supply connector pin-outs are shown below in Table 4.

TABLE 4
Power Supply Output Connector Pin-out

| Pin # | Pin Name | Description |
|---|---|---|
| PB RH1 | +12 V RET | Main Power Return (Blade) |
| PB RH2 | +12 V RET | Main Power Return (Blade) |
| PB RH3 | +12 V RET | Main Power Return (Blade) |
| PB RH4 | +12 V | 12 V Power Output (Blade) |
| PB RH5 | +12 V | 12 V Power Output (Blade) |
| PB RH6 | +12 V | 12 V Power Output (Blade) |
| A1 | PS ON | Power supply control |
| A2 | +12VRS RETURN | +12 V RET Remote Sense |
| A3 | TEMP_OK | Within allowable temp range (PU) |
| A4 | PS_SEATED | Present - active low (Short pin) |
| | | (PU) |
| A5 | +3V3SB | 3.3 V Standby Output |
| A6 | +3V3SB GND | 3.3 V Standby Return |
| B1 | AC OK | Input voltage within spec |
| B2 | +12VRS | +12 V Remote Sense |
| B3 | +12 V_ISHARE | 12 V current Share Pin. |
| B4 | PS_INHIBIT | Grounded in system to enable (Short |
| | | pin) |
| B5 | +3V3SB | 3.3 V Standby Output |
| B6 | +3V3SB GND | 3.3 V Standby Return |
| C1 | SDA | EEPROM Serial Data I/O |
| C2 | SCL | EEPROM Serial Clock Input |
| C3 | PWR_GD | Indicates output with range |
| C4 | FAN FAIL | Indicates Fail failure. |
| C5 | +3V3SB | 3.3 V Standby Output |
| C6 | +3V3SB GND | 3.3 V Standby Return |
| D1 | A0 | EPPROM Address Bit 0 Input |
| D2 | A1 | EEPROM Address Bit 1 Input |
| D3 | S INT | Serial Interrupt |
| D4 | +3V3SBRS | 3.3 V Standby Remote Sense |
| D5 | +3V3SB | 3.3 V Standby Output |
| D6 | +3V3SB GND | 3.3 V Standby Return |

The power supply has one Bi-color LED on the back of the unit. The power supply LED condition indications are set forth below in Table 5.

TABLE 5
Power Supply Output Connector Pin-out

| | POWER SUPPLY LED |
|---|---|
| POWER SUPPLY CONDITION | GREEN/RED |
| No AC power to all PSU. | OFF |
| AC present/Standby outputs ON. | Blinking Green |
| Power supply DC outputs ON and OK. | Green |
| Power supply failure (Over Current), UVP | Blinking Red |
| Power supply failure due to OVP, OTP and | Red |
| Fan Fail | |

The fans provide 474 CFM of airflow in a redundant configuration or 424 CFM in non redundant configuration. Air flow is front to back, for the entire chassis, not counting the disks and power supplies. The fan controller resides on the IO board, which will drive the fan speed and monitor the tachometer signals. Each fan has an LED to identify a failure.

The I2C bus is a 2 pin serial bus that interconnects EEPROMs, fan controllers, power supplies, temperature sensors, and other devices that are used to monitor the health and status of the system. In some cases, such as temperature, a separate interrupt immediately alerts the processors in case of a problem. All components connected to the SP_I2C bus are powered from the 3.3V Auxiliary rail.

The USB connector is shown in FIG. 13 and the pin-outs are shown below in Table 6.

TABLE 6
USB Connector Pin-out

| Pin # | Pin Name | Description |
|---|---|---|
| 1 | +5 V | +5 V Supply |
| 2 | Data− | Negative side of differential pair for data |
| 3 | Data+ | Positive side of differential pair for data |
| 4 | Gnd | Ground |

The Serial connector is shown in FIG. 14 and the pin-outs are shown below in Table 7.

TABLE 7
Serial Connector Pin-out

| Pin # | Pin Name | Description |
|---|---|---|
| 1 | CTS | Clear To Send |
| 2 | DCD | Data Carrier Detect |
| 3 | TXD | Transmit Data |
| 4 | GND | Ground |
| 5 | GND | Ground |
| 6 | RXD | Receive Data |
| 7 | DTR | Data Terminal Ready |
| 8 | RTS | Ready To Send |

The VGA connector is shown in FIG. 15 and the pin-outs are shown below in Table 8.

TABLE 8
VGA Connector Pin-out

| Pin # | Pin Name | Description |
|---|---|---|
| 1 | RED | Red Video |
| 2 | GRN | Green Video |
| 3 | BLU | Blue Video |
| 4 | ID2 | ID2 (Ground) |
| 5 | GND | Ground |
| 6 | R_GND | Red Video Return (Ground) |
| 7 | G_GND | Green Video Return (Ground) |
| 8 | B_GND | Blue Video Return (Ground) |
| 9 | KEY | No Pin |
| 10 | S_GND | Sync Return (Ground) |
| 11 | ID0 | ID0 (Ground) |
| 12 | ID1/SDA | ID1 (No Connect) |
| 13 | HSYNC | Horizontal Sync |
| 14 | VSYNC | Vertical Sync |
| 15 | ID3/SCL | No Connect |

The 10/100/1000BaseT connector is shown in FIG. 16 and the pin-outs are shown below in Table 9.

TABLE 9
10/100/1000BaseT Connector Pin-out

| Pin # | Pin Name | Description |
|---|---|---|
| 1 | TP0+ | Positive Side of Data Pair 0 |
| 2 | TP0− | Negative Side of Data Pair 0 |
| 3 | TP1+ | Positive Side of Data Pair 1 |
| 4 | TP2+ | Positive Side of Data Pair 2 |
| 5 | TP2− | Negative Side of Data Pair 2 |
| 6 | TP1− | Negative Side of Data Pair 1 |
| 7 | TP3+ | Positive Side of Data Pair 3 |
| 8 | TP3− | Negative Side of Data Pair 3 |

The Serial Attached SCSI (SAS) connector is shown in FIG. 17 and the pin-outs are shown below in Table 10.

TABLE 10
Serial Attached SCSI (SAS) Connector Pin-out
Pin-out Table
Signal Segment Key

| | | | |
|---|---|---|---|
| Signal | S1 | Gnd | 2^{nd} mate |
| Segment | S2 | TX+ | Transmit from PHY to |
| | S3 | TX− | hard drive |
| | S4 | Gnd | 2^{nd} mate |
| | S5 | RX− | Receive from hard drive |
| | S6 | RX+ | to PHY |
| | S7 | Gnd | 2^{nd} mate |
| Back- | S8 | Gnd | 2^{nd} mate |
| side | S9 | | |
| Signal | S10 | | |
| | S11 | Gnd | 2^{nd} mate |
| | S12 | | |
| | S13 | | |
| | S14 | Gnd | 2^{nd} mate |
| Power | P1 | 3.3 V | Not Supported |
| Segment | P2 | 3.3 V | Not Supported |
| | P3 | 3.3 V | Not Supported |
| | P4 | Gnd | 1^{st} mate |
| | P5 | Gnd | 2^{nd} mate |
| | P6 | Gnd | 2^{nd} mate |
| | P7 | 5.0 V | Pre-charge, 2^{nd} mate |
| | P8 | 5.0 V | |
| | P9 | 5.0 V | |
| | P10 | Gnd | 2^{nd} mate |
| | P11 | Reserved | Grounded |
| | P12 | Gnd | 1^{st} mate |
| | P13 | 12.0 V | Pre-charge, 2^{nd} mate |
| | P14 | 12.0 V | |
| | P15 | 12.0 V | |

Power Segment Key

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A server, comprising:
a plurality of fans arranged along an inside surface of a front side of the server;
a backplane disposed behind the plurality of fans;
a plurality of CPU modules operatively connected to the backplane;
and
a plurality of I/O components disposed behind the plurality of CPU modules.

2. The server of claim 1, wherein the backplane is arranged to support at least one of standard I/O and modular I/O.

3. The server of claim 1, wherein the plurality of fans are arranged in a plurality of rows.

4. The server of claim 1, wherein the plurality of fans comprises a hot-swappable fan.

5. The server of claim 1, further comprising:
a plurality of storage devices accessible from the front side of the server;
a plurality of power supplies accessible from a rear side of the server; and
at least one fan disposed between the plurality of storage devices and the plurality of power supplies.

6. The server of claim 1, wherein air flow provided to the plurality of CPU modules by the plurality of fans is not obstructed.

7. The server of claim 1, wherein air flow provided to the plurality of CPU modules by the plurality of fans is uniform.

8. An apparatus, comprising:
a first section comprising:
dual-redundant cooling devices,
a motherboard disposed behind the dual-redundant cooling devices, and
at least one CPU module vertically connected to the motherboard; and
a second section comprising:
at least one disk drive accessible from a front side of the apparatus,
at least one power supply accessible from a rear side of the apparatus, and
at least one cooling device disposed between the at least one disk drive and the at least one power supply,
wherein airflow in the first section is separate from airflow in the second section.

9. The apparatus of claim 8, wherein at least one of the dual-redundant cooling devices is hot-swappable.

10. The apparatus of claim 8, wherein the at least one CPU module comprises:
a microprocessor;
a heat sink disposed over the microprocessor; and
and a connector arranged to mate with a connector disposed on the motherboard,
wherein at least a portion of the heat sink is arranged to overhang at least a portion of the connector.

11. The apparatus of claim 8, the first section further comprising:
I/O components disposed behind the at least one CPU module.

12. The apparatus of claim 8, wherein the motherboard is arranged to support at least one of standard I/O and modular I/O.

13. The apparatus of claim 8, wherein air flow in the first section is uniformly provided to the at least CPU module by the dual-redundant cooling devices.

14. The apparatus of claim 8, wherein at least one of the dual-redundant cooling devices is a fan at least partially housed in a chassis secured along a front side portion of the apparatus.

15. A rackmount server, comprising:
dual-redundant hot-swappable fans disposed along a front vented inner surface of the rackmount server;
a plurality of CPU modules operatively connected to a backplane horizontally disposed behind the dual-redundant hot-swappable fans; and
I/O circuitry disposed behind the plurality of CPU modules,
wherein a first airflow zone in which air flow is provided by the dual-redundant hot-swappable fans to the plurality of CPU modules is separate from a second airflow zone in which air flow is provided to an internal power supply unit of the rackmount server.

16. The rackmount server of claim 15, wherein the backplane is configured to support at least one of standard I/O and modular I/O.

17. The rackmount server of claim 15, wherein air flow in the second airflow zone is provided to at least one disk drive accessible from a front side of the rackmount server.

18. The rackmount server of claim 15, wherein at least one of the plurality of CPU modules comprises:
an integrated circuit;
a heat sink disposed over the integrated circuit; and
and a connector arranged to mate with a connector disposed on the backplane,
wherein at least a portion of the heat sink is arranged to overhang at least a portion of the connector.

19. The rackmount server of claim 15, wherein air flow in the first airflow zone is substantially uniform.

20. The rackmount server of claim 15, wherein at least one of the plurality of CPU modules is vertically disposed in connection with the backplane.
